(19) United States
(12) Patent Application Publication
(10) Pub. No.: US 2022/0123733 A1
(43) Pub. Date: Apr. 21, 2022

(54) ACOUSTIC WAVE FILTER

(71) Applicant: Murata Manufacturing Co., Ltd., Nagaokakyo-shi (JP)

(72) Inventor: Tetsuro OKUDA, Nagaokakyo-shi (JP)

(21) Appl. No.: 17/562,059

(22) Filed: Dec. 27, 2021

Related U.S. Application Data
(63) Continuation of application No. PCT/JP2020/019613, filed on May 18, 2020.

(30) Foreign Application Priority Data
Jun. 28, 2019 (JP) 2019-120929

(51) Int. Cl. H03H 9/64; H03H 9/145; H03H 9/25

(52) U.S. Cl. CPC H03H 9/6483; H03H 9/25; H03H 9/145

(57) ABSTRACT

An acoustic wave filter includes input and output terminals, and series arm and parallel arm circuits. The series arm circuit includes first and second series arm resonators connected in series between the input and output terminals. The parallel arm circuit includes a parallel arm resonator connected between the series arm circuit and a ground potential. Each of the first and second series arm resonators is a SAW resonator including a piezoelectric substrate and an IDT electrode on the piezoelectric substrate, and has a characteristic that a fractional band width increases with a decrease in a thickness of the piezoelectric substrate. An anti-resonant frequency of the first series arm resonator is lower than an anti-resonant frequency of the second series arm resonator. A wavelength of a signal passing through the first series arm resonator is shorter than a wavelength of a signal passing through the second series arm resonator.

### CROSS REFERENCE TO RELATED APPLICATIONS

This application claims the benefit of priority to Japanese Patent Application No. 2019-120929 filed on Jun. 28, 2019 and is a Continuation Application of PCT Application No. PCT/JP2020/019613 filed on May 18, 2020. The entire contents of each application are hereby incorporated herein by reference.

### BACKGROUND OF THE INVENTION

### 1. Field of the Invention

The present disclosure relates to an acoustic wave filter, and more particularly, to a technique to improve steepness of attenuation characteristics in a ladder filter which includes a plurality of surface acoustic wave (SAW) resonators.

### 2. Description of the Related Art

As a band pass filter, a ladder acoustic wave filter (hereinafter also referred to as a “ladder filter”) including a plurality of acoustic wave resonators cascaded as disclosed in Japanese Unexamined Patent Application Publication No. 2011-114826 has been known.

In a ladder filter, a resonant frequency of each series arm resonator and an anti-resonant frequency of each parallel arm resonator are set near a center frequency of a desired pass band, an anti-resonant frequency of the series arm resonator is located at an attenuation pole near an upper-limit frequency on a high-frequency side, and a resonant frequency of the parallel arm resonator is located at an attenuation pole near a lower-limit frequency at a low-frequency side, thus forming the pass band.

A ladder filter as disclosed in Japanese Unexamined Patent Application Publication No. 2011-114826 may be used in electronic equipment, such as a cellular phone or a smartphone.

To provide large capacitance and high-speed communication in the above-described electronic equipment, the fifth generation mobile communication system (5G) is under development. With the development, there is a need for further widening of a band width of a band pass filter. For band width widening, it is important to ensure steepness of attenuation characteristics between a pass band and an attenuation range.

### SUMMARY OF THE INVENTION

Preferred embodiments of the present invention provide ladder acoustic wave filters each with improved steepness of attenuation characteristics at a pass band end portion.

An acoustic wave filter according to a preferred embodiment of the present invention includes an input terminal, an output terminal, a series arm circuit, and a parallel arm circuit. The series arm circuit includes a first series arm resonator and a second series arm resonator connected in series between the input terminal and the output terminal. The parallel arm circuit includes at least one parallel arm resonator connected between the series arm circuit and a ground potential. Each of the first series arm resonator and the second series arm resonator is a SAW resonator including a piezoelectric substrate and a comb-shaped (an interdigital transducer (IDT)) electrode on the piezoelectric substrate. Each series arm resonator has a characteristic that a fractional band width increases with a decrease in a thickness of the piezoelectric substrate which is normalized with a wavelength of a signal passing through the series arm resonator. An anti-resonant frequency of the first series arm resonator is lower than an anti-resonant frequency of the second series arm resonator. A wavelength of a signal passing through the first series arm resonator is shorter than a wavelength of a signal passing through the second series arm resonator.

An acoustic wave filter according to a preferred embodiment of the present invention includes an input terminal, an output terminal, a series arm circuit, and a parallel arm circuit. The series arm circuit includes a plurality of series arm resonators connected in series between the input terminal and the output terminal. The parallel arm circuit includes at least one parallel arm resonator connected between the series arm circuit and a ground potential. Each of the plurality of series arm resonators is a SAW resonator including a piezoelectric substrate and an IDT electrode on the piezoelectric substrate. Each of the plurality of series arm resonators has a characteristic that a fractional band width increases with a decrease in a thickness of the piezoelectric substrate which is normalized with a wavelength of a signal passing through the series arm resonator. A wavelength of a signal passing through one of the plurality of series arm resonators with a lowest anti-resonant frequency is shorter than wavelengths of signals passing through remaining series arm resonators of the plurality of series arm resonators.

An acoustic wave filter according to a preferred embodiment of the present invention includes an input terminal, an output terminal, a series arm circuit, and a parallel arm circuit. The series arm circuit includes a first series arm resonator and a second series arm resonator connected in series between the input terminal and the output terminal. The parallel arm circuit includes at least one parallel arm resonator connected between the series arm circuit and a ground potential. Each of the first series arm resonator and the second series arm resonator is a SAW resonator including a piezoelectric substrate and a comb-shaped electrode on the piezoelectric substrate. For each series arm resonator, a thickness of the piezoelectric substrate is less than or equal to about 0.7λ, where λ is a wavelength of a signal passing through the series arm resonator. An anti-resonant frequency of the first series arm resonator is lower than an anti-resonant frequency of the second series arm resonator. A wavelength of a signal passing through the first series arm resonator is shorter than a wavelength of a signal passing through the second series arm resonator.

According to preferred embodiments of the present invention, acoustic wave filters each include two series arm resonators (a first series arm resonator and a second series arm resonator) with different anti-resonant frequencies, and a wavelength of a high-frequency signal passing through the first series arm resonator with a lower anti-resonant frequency is set lower than a wavelength of a high-frequency signal passing through the second series arm resonator. This configuration enables improvement of steepness of an attenuation characteristic on a high-frequency side in a pass band of the filter.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a diagram showing one example of a configuration of a ladder acoustic wave filter according to a preferred embodiment of the present invention.

FIG. 2 shows one example (comparative example) of design parameters for acoustic wave resonators of the acoustic wave filter in FIG. 1.

FIGS. 3A and 3B are graphs for explaining a pass band in a ladder filter.

FIG. 4 is a graph showing one example of a relationship between a normalized film thickness of a piezoelectric substrate and a fractional band width.

FIG. 5 is a graph showing one example of a relationship between a fractional band width and a wavelength of a high-frequency signal passing through a filter.

FIGS. 6A and 6B are views showing a configuration of an acoustic wave resonator used in an acoustic wave filter according to a preferred embodiment of the present invention.

FIG. 7 is a view showing a configuration of an acoustic wave resonator without a reflecting layer.

FIG. 8 is a graph showing one example of a relationship between a film thickness of an IDT electrode and a fractional band width.

FIG. 9 shows design parameters for acoustic wave resonators in an acoustic wave filter according to an example of a preferred embodiment of the present invention.

FIG. 10 is a graph for explaining attenuation factors in the acoustic wave filter according to the example and an acoustic wave filter according to the comparative example.

FIG. 11 is a graph obtained by enlarging a region RG1 in FIG. 10.

FIG. 12 is a graph for explaining fractional band widths of series arm resonators S3-2 in the example and the comparative example.

### DETAILED DESCRIPTION OF THE PREFERRED EMBODIMENTS

Preferred embodiments of the present invention will be described in detail below with reference to the drawings. The same or corresponding portions in the drawings are denoted by the same reference characters and a description thereof will not be repeated.

### Basic Configuration of Acoustic Wave Filter

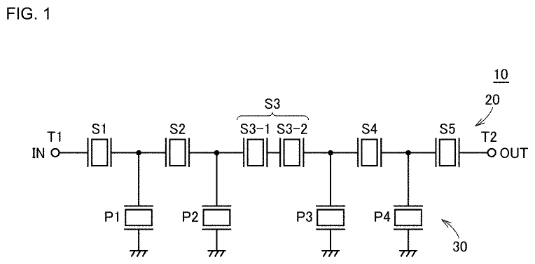

FIG. 1 is a diagram showing one example of a configuration of a ladder acoustic wave filter 10 according to a preferred embodiment of the present invention. Referring to FIG. 1, the acoustic wave filter 10 includes a series arm circuit 20 including a plurality of series arm resonators and a parallel arm circuit 30 connected between the series arm circuit 20 and a ground potential.

The series arm circuit 20 includes series arm resonators S1 to S5 which are connected in series between an input terminal T1 and an output terminal T2. The series arm resonator S3 includes series arm resonators S3-1 and S3-2 which are connected in series.

The parallel arm circuit 30 includes a plurality of parallel arm resonators P1 to P4. The parallel arm resonator P1 is connected between the ground potential and a connection node between the series arm resonator S1 and the series arm resonator S2. The parallel arm resonator P2 is connected between the ground potential and a connection node between the series arm resonator S2 and the series arm resonator S3-1. The parallel arm resonator P3 is connected between the ground potential and a connection node between the series arm resonator S3-2 and the series arm resonator S4. The parallel arm resonator P4 is connected between the ground potential and a connection node between the series arm resonator S4 and the series arm resonator S5.

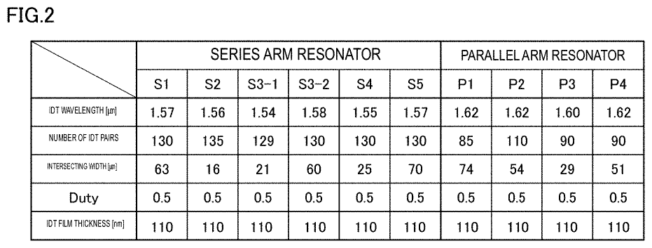

FIG. 2 shows one example of design parameters for the acoustic wave resonators of the acoustic wave filter 10 shown in FIG. 1. As design parameters, a wavelength (IDT wavelength) of a high-frequency signal passing through an IDT electrode, the number of pairs of IDT electrode fingers (the number of IDT pairs), an intersecting width of the IDT electrode fingers, a line width (duty) of the IDT electrode fingers, and a film thickness of the IDT electrode are shown. The wavelength of a high-frequency signal passing through the IDT electrode corresponds to an electrode pitch of the IDT electrode.

By adjusting resonant frequencies and anti-resonant frequencies of acoustic wave resonators in a ladder filter as described above, a band pass filter with a desired pass band can be provided.

### Bandpass Characteristics of Ladder Filter

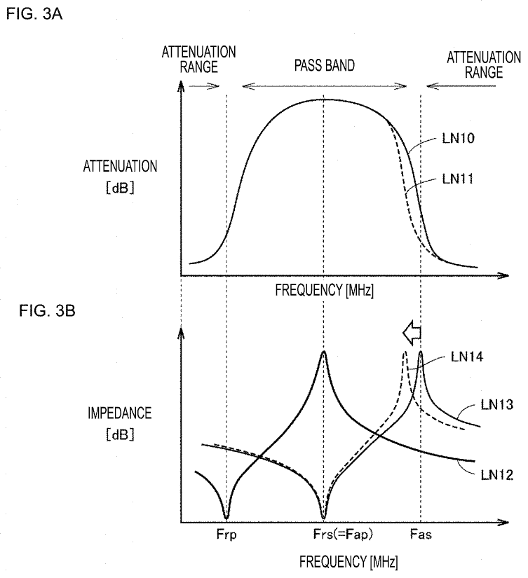

FIGS. 3A and 3B are graphs for explaining a pass band in a ladder filter. An impedance (LN13) of a series arm resonator and an impedance (LN12) of a parallel arm resonator are shown in a lower portion (FIG. 3B) of FIGS. 3A and 3B. Further, bandpass characteristics (an attenuation) of the ladder filter are shown in an upper portion (FIG. 3A).

As shown in the lower portion (FIG. 3B) of FIGS. 3A and 3B, a resonant frequency Frs of each series arm resonator and an anti-resonant frequency Fap of each parallel arm resonator are set near a center frequency of a target pass band. At this time, an upper-limit frequency on a high-frequency side of a pass band is defined by an attenuation pole which is determined by an anti-resonant frequency Fas of the series arm resonator. Further, a lower-limit frequency on a low-frequency side of the pass band is defined by an attenuation pole which is determined by a resonant frequency Frp of the parallel arm resonator. In this manner, a band pass filter is provided, the band pass filter having a pass band between the resonant frequency Frp of the parallel arm resonator and the anti-resonant frequency Fas of the series arm resonator and having attenuation ranges in a frequency range lower than the resonant frequency Frp and a frequency range higher than the anti-resonant frequency Fas, as indicated by a line LN10 in FIG. 3A.

To widen a pass band of a band pass filter, it is generally preferable to widen the spacing (that is, a fractional band width) between a resonant frequency and an anti-resonant frequency of each acoustic wave resonator. Here, a fractional band width is defined as a difference (band width) between a resonant frequency Fr and an anti-resonant frequency Fa with respect to the resonant frequency Fr (fractional band width=(Fa−Fr)/Fr).

Meanwhile, to achieve a high signal to noise ratio between a pass band and an attenuation range outside the pass band, it is necessary to achieve a high attenuation factor in the attenuation range. To this end, it is important to improve steepness of attenuation characteristics near an upper-limit frequency and a lower-limit frequency of a pass band.

In a ladder filter, an upper limit of a pass band is determined by a combination of anti-resonant frequencies of a plurality of series arm resonators, as described above. A fractional band width of one with a lowest anti-resonant frequency of the series arm resonators contributes greatly to steepness of an attenuation characteristic. For this reason, steepness of an attenuation characteristic on an upper-limit side (high-frequency side) of a pass band can be improved by making the fractional band width of the series arm resonator smaller than the fractional band widths of the other series arm resonators.

Thus, in the present preferred embodiment, steepness of an attenuation characteristic on a high-frequency side of a pass band is improved (a broken line LN11 in FIGS. 3A and 3B) by making a fractional band width of a series arm resonator with a lowest anti-resonant frequency smaller (a broken line LN14 in FIGS. 3A and 3B). Relationships between a fractional band width and design parameters for an acoustic wave resonator will be described below.

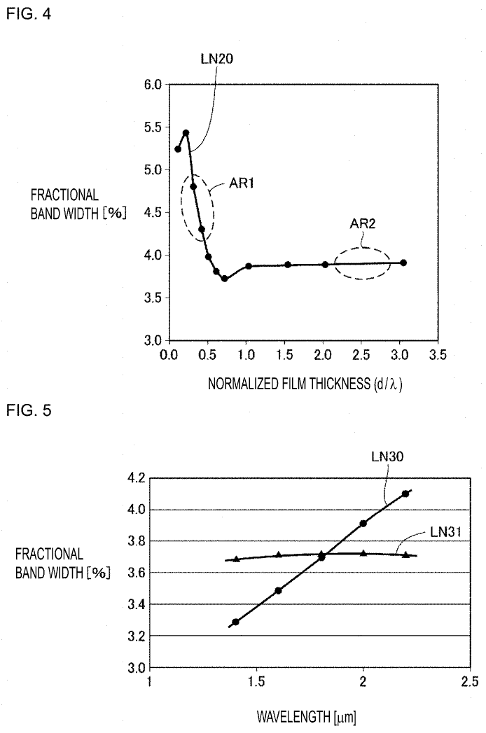

FIG. 4 is a graph showing a relationship between a normalized film thickness of a piezoelectric substrate and a fractional band width. In FIG. 4, a horizontal axis indicates a normalized film thickness while a vertical axis indicates a fractional band width. Here, the “normalized film thickness” is defined as a film thickness d of a piezoelectric substrate with respect to an IDT wavelength λ (normalized film thickness=d/λ).

Referring to FIG. 4, if the normalized film thickness is larger than about 1.0, that is, the film thickness d of the piezoelectric substrate is more than the IDT wavelength λ, the fractional band width has the same or substantially the same value (about 3.7%) regardless of the magnitude of the normalized film thickness (a region AR2 in FIG. 4), as indicated by a line LN20 in FIG. 4. On the other hand, if the normalized film thickness is smaller than about 0.7, the fractional band width increases greatly with a decrease in a value of the normalized film thickness (a region AR1 in FIG. 4).

That is, in the region AR1 in FIG. 4, the fractional band width decreases with an increase in the film thickness d of the piezoelectric substrate when the IDT wavelength λ is constant. When the film thickness d of the piezoelectric substrate is constant, the fractional band width decreases with a decrease in the IDT wavelength λ (that is, an electrode pitch).

FIG. 5 is a representation of the above-described latter relationship. In FIG. 5, a horizontal axis indicates the IDT wavelength λ while a vertical axis indicates the fractional band width. In FIG. 5, a line LN30 indicates a change in the fractional band width in a case where the wavelength λ is varied when the normalized film thickness d/λ of the piezoelectric substrate is small (the region AR1 in FIG. 4). On the other hand, a line LN31 indicates a change in the fractional band width in a case where the wavelength λ is varied when the normalized film thickness d/λ of the piezoelectric substrate is large (the region AR2 in FIG. 4). As can be seen from FIG. 5, the fractional band width can be reduced by reducing the normalized film thickness d/λ of the piezoelectric substrate and reducing the IDT wavelength λ.

### Configuration of Acoustic Wave Resonator

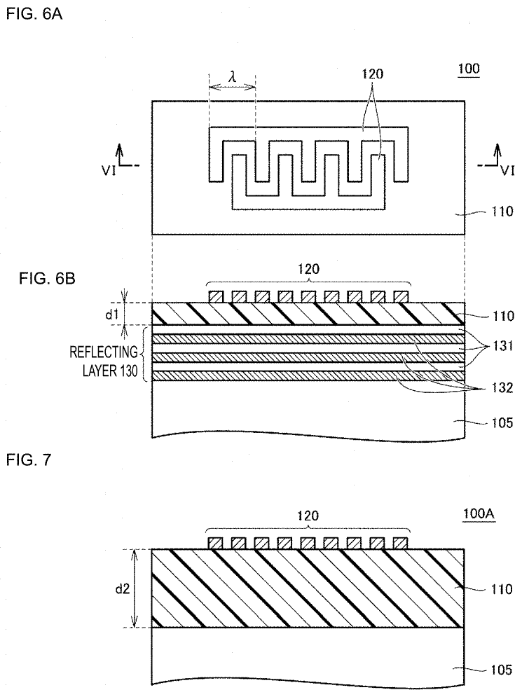

FIGS. 6A and 6B are views showing a configuration of an acoustic wave resonator 100 which is used in the acoustic wave filter 10 according to the present preferred embodiment. In FIGS. 6A and 6B, a plan view of the acoustic wave resonator 100 is shown in an upper portion (FIG. 6A) while a sectional view of the acoustic wave resonator 100 taken along line VI-VI is shown in a lower portion (FIG. 6B).

Referring to FIGS. 6A and 6B, the acoustic wave resonator 100 includes a support substrate 105, a piezoelectric substrate 110, an IDT electrode 120, and a reflecting layer 130.

The support substrate 105 is a semiconductor substrate which is made of a material, such as silicon (Si), gallium arsenide (GaAs), gallium nitride (GaN), or silicon carbide (SiC), for example. The piezoelectric substrate 110 is stacked above the support substrate 105 with the reflecting layer 130 interposed therebetween. In the example of the acoustic wave resonator 100 in FIGS. 6A and 6B, the support substrate 105 is made of silicon.

The piezoelectric substrate 110 is made of a piezoelectric material, such as lithium tantalate (LiTaO₃: LT), lithium niobate (LiNbO₃: LN), aluminum nitride, zinc oxide, or piezoelectric zirconate titanate (PZT), for example. The piezoelectric substrate 110 may be made of a single-crystal material of the above-described piezoelectric material or may be made of a piezoelectric laminated material made of LT or LN.

One pair of IDT electrodes 120 are provided on an upper surface of the piezoelectric substrate 110. The IDT electrodes 120 are made using a conductive material, such as a single-component metal made of at least one of aluminum, copper, silver, gold, titanium, tungsten, platinum, chrome, nickel, and molybdenum or an alloy composed mainly thereof, for example. The piezoelectric substrate 110 and the IDT electrodes 120 define a SAW resonator.

A film thickness d1 of the piezoelectric substrate 110 is preferably set to less than or equal to a wavelength λ which is defined by an electrode pitch of the IDT electrode 120. The setting of the film thickness dl of the piezoelectric substrate 110 in this manner allows increase in a coupling coefficient and a Q factor.

The reflecting layer 130 includes a plurality of low-acoustic-velocity films 131 and a plurality of high-acoustic-velocity films 132. The low-acoustic-velocity films 131 and the high-acoustic-velocity films 132 are alternately arranged in a stacking direction from the piezoelectric substrate 110 toward the support substrate 105.

The low-acoustic-velocity film 131 is made of a material in which an acoustic velocity of a bulk wave which propagates through the low-acoustic-velocity film 131 is lower than an acoustic velocity of a bulk wave which propagates through the piezoelectric substrate 110. In other words, the low-acoustic-velocity film 131 is made of a material having an acoustic impedance lower than that of the piezoelectric substrate 110. The low-acoustic-velocity film 131 is made of a dielectric, such as silicon dioxide, glass, silicon oxynitride, or tantalum oxide, or a compound obtained by adding fluorine, carbon, boron, or the like to silicon dioxide, for example.

The high-acoustic-velocity film 132 is made of a material in which an acoustic velocity of a bulk wave which propagates through the high-acoustic-velocity film 132 is higher than an acoustic velocity of an acoustic wave which propagates through the piezoelectric substrate 110. In other words, the high-acoustic-velocity film 132 is made of a material having an acoustic impedance higher than that of the piezoelectric substrate 110. The high-acoustic-velocity film 132 is made of a material, such as aluminum nitride, silicon nitride, aluminum oxide (alumina), silicon oxynitride, silicon carbide, diamond-like carbon (DLC), or diamond, for example.

With the configuration, in which the low-acoustic-velocity films 131 and the high-acoustic-velocity films 132 are stacked underneath the piezoelectric substrate 110, the high-acoustic-velocity films 132 and the low-acoustic-velocity films 131 define and function as a reflecting layer (mirror layer) which reflects a surface acoustic wave. The reflecting layer 130 is an acoustic Bragg reflector.

That is, a surface acoustic wave which leaks out from the piezoelectric substrate 110 in a direction toward the support substrate 105 is reflected by the high-acoustic-velocity film 132 due to a difference in propagating acoustic velocity and is confined as a standing wave in the low-acoustic-velocity film 131. As described above, since loss of acoustic energy of a surface acoustic wave which is propagated by the piezoelectric substrate 110 is reduced, surface acoustic waves can be efficiently propagated. Note that, although an example where the reflecting layer 130 includes a plurality of low-acoustic-velocity films 131 and a plurality of high-acoustic-velocity films 132 is illustrated in FIGS. 6A and 6B, the reflecting layer 130 may include a single low-acoustic-velocity film 131 and a single high-acoustic-velocity film 132.

With the configuration with the reflecting layer 130 as in FIGS. 6A and 6B, the film thickness of the piezoelectric substrate 110 can be smaller (d1<d2) than that of an acoustic wave resonator 100A without the reflecting layer 130, as shown in FIG. 7. As described with reference to FIG. 5, a fractional band width can be reduced by reducing a wavelength λ (an electrode finger pitch) of the IDT electrode 120 of one of the series arm resonators with a lowest anti-resonant frequency included in the series arm circuit 20. This enables improvement of the steepness of an attenuation characteristic on a high-frequency side of a pass band.

Since a velocity v of a high-frequency signal propagating through the piezoelectric substrate 110 is constant or substantially constant, if the wavelength λ of the IDT electrode 120 is decreased, a resonant frequency of the IDT electrode 120 increases due to the relationship v=f·λ. For this reason, in order to cause the resonant frequency to coincide with those in other series arm resonators, the resonant frequency is reduced by, for example, increasing a film thickness of the IDT electrode 120, increasing a thickness of a dielectric film to be stacked on the IDT electrode 120, or increasing a line width (duty) of an electrode finger to increase a weight of the IDT electrode 120.

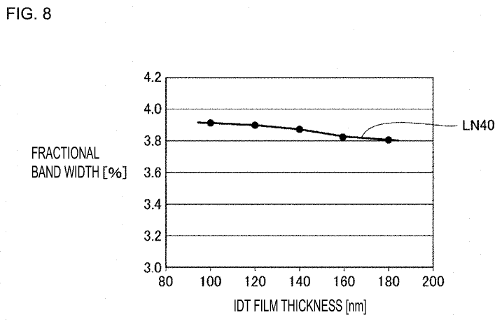

FIG. 8 is a graph showing one example of a relationship between the film thickness of the IDT electrode 120 and the fractional band width. In FIG. 8, a horizontal axis indicates the film thickness of the IDT electrode 120 while a vertical axis indicates the fractional band width. As can be seen from FIG. 8, a change in the film thickness of the IDT electrode 120 has a small effect on the fractional band width. It is thus possible to adjust the resonant frequency without affecting the fractional band width by increasing the film thickness of the IDT electrode 120 or stacking a dielectric film on the IDT electrode 120, as described above.

### Example

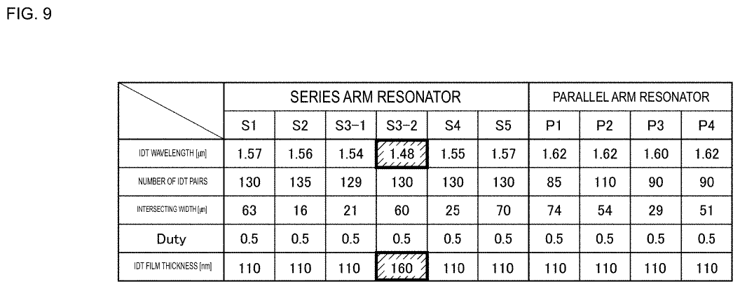

Effects of an example where an IDT wavelength of a series arm resonator with a lowest anti-resonant frequency is reduced will be described based on the present preferred embodiment with reference to FIGS. 9 to 12.

FIG. 9 shows one example of design parameters for acoustic wave resonators in an acoustic wave filter according to the example. Since a series arm resonator with a lowest anti-resonant frequency is the series arm resonator S3-2 in the case of the design parameters shown in FIG. 2, an IDT wavelength of the series arm resonator S3-2 has been reduced from about 1.58 μm to about 1.48 μm in FIG. 9. Accordingly, an IDT film thickness of the series arm resonator S3-2 has been changed from about 110 nm to 160 about nm to reduce a resonant frequency of the series arm resonator S3-2.

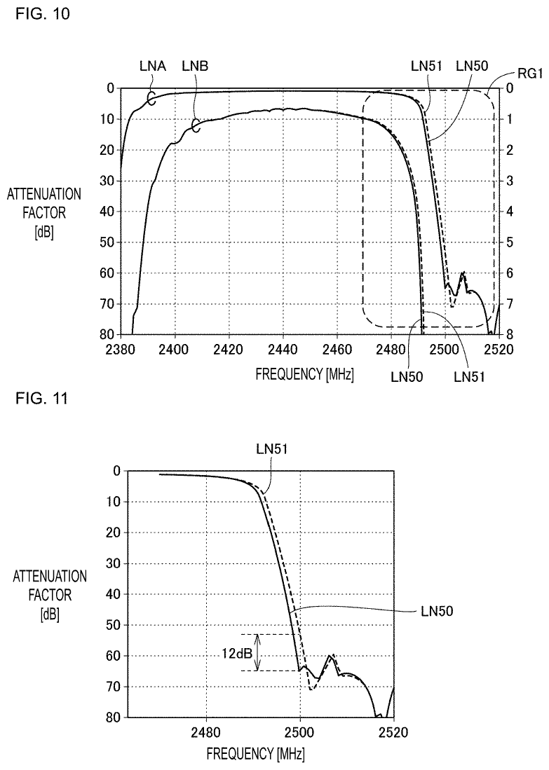

FIGS. 10 and 11 are graphs for explaining bandpass characteristics in the acoustic wave filter according to the example (FIG. 9) and an acoustic wave filter according to a comparative example (FIG. 2). FIG. 11 is a graph obtained by enlarging a region RG1 in FIG. 10. In each of FIGS. 10 and 11, a horizontal axis indicates a frequency while a vertical axis indicates an attenuation factor. In FIGS. 10 and 11, a solid line LN50 indicates an attenuation factor in the example while a broken line LN51 indicates an attenuation factor in the comparative example. In FIG. 10, a line LNB is obtained by enlarging a line LNA along the vertical axis.

Referring to FIGS. 10 and 11, an attenuation near 2500 MHz is about 53 dB in the acoustic wave filter according to the comparative example while an attenuation near 2500 MHz is about 65 dB in the acoustic wave filter according to the example, which is an improvement. Thus, the acoustic wave filter according to the example has improved steepness of an attenuation characteristic on a high-frequency side of a pass band compared with the acoustic wave filter according to the comparative example.

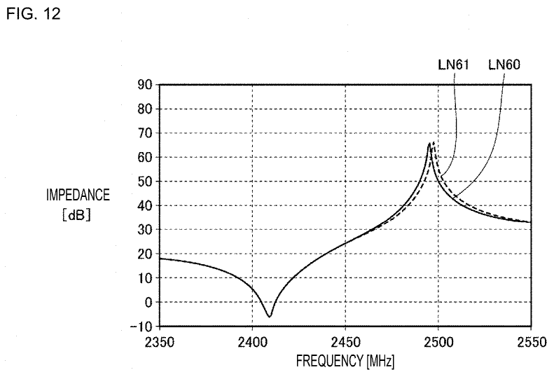

FIG. 12 is a graph for explaining fractional band widths of the series arm resonators S3-2 in the example and the comparative example. In FIG. 12, a horizontal axis indicates a frequency while a vertical axis indicates an impedance. In FIG. 12, a solid line LN60 indicates an impedance of the series arm resonator S3-2 in the example, while a broken line LN61 indicates an impedance of the series arm resonator S3-2 in the comparative example.

As shown in FIG. 12, if the example and the comparative example have the same or substantially the same resonant frequency by IDT film thickness adjustment, an anti-resonant frequency in the example is lower than an anti-resonant frequency in the comparative example. For this reason, the fractional band width is reduced from about 3.8% to about 3.6%. That is, with the reduction in fractional band width associated with the anti-resonant frequency, the steepness of the attenuation characteristic on the high-frequency side of the pass band is able to be improved.

As described above, the steepness of an attenuation characteristic on a high-frequency side of a pass band can be improved in a ladder acoustic wave filter by shortening an IDT electrode pitch (a wavelength λ) and lowering a fraction band width in a series arm resonator with a lowest anti-resonant frequency.

Configurations of the series arm circuit 20 and the parallel arm circuit 30 in the acoustic wave filter 10 described above are not limited to those shown in FIG. 1. The design parameters for the acoustic wave resonators included in the series arm circuit 20 and the parallel arm circuit 30 shown in FIGS. 2 and 9 are merely illustrative, and each parameter is appropriately set in accordance with a center frequency and a band width of a pass band.

Although a band pass filter which enables only a predetermined frequency component to pass through has been illustrated as an example in the above description, the features of preferred embodiments of the present invention can also be applied to a trap filter which attenuates only a predetermined frequency component.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter comprising:
an input terminal;
an output terminal;
a series arm circuit including a first series arm resonator and a second series arm resonator connected in series between the input terminal and the output terminal; and
a parallel arm circuit including at least one parallel arm resonator connected between the series arm circuit and a ground potential; wherein
each of the first series arm resonator and the second series arm resonator is a surface acoustic wave (SAW) resonator including a piezoelectric substrate and an interdigital transducer (IDT) electrode on the piezoelectric substrate, and has a characteristic that a fractional band width increases with a decrease in a thickness of the piezoelectric substrate, which is normalized with a wavelength of a signal passing through the series arm resonator;
an anti-resonant frequency of the first series arm resonator is lower than an anti-resonant frequency of the second series arm resonator; and
a wavelength of a signal passing through the first series arm resonator is shorter than a wavelength of a signal passing through the second series arm resonator.

2. The acoustic wave filter according to claim 1, wherein each of the first series arm resonator and the second series arm resonator includes a reflecting layer on a surface of the piezoelectric substrate opposite to a surface on which the IDT electrode is provided.

3. The acoustic wave filter according to claim 1, wherein an electrode finger pitch of the IDT electrode of the first series arm resonator is smaller than an electrode finger pitch of the IDT electrode of the second series arm resonator.

4. The acoustic wave filter according to claim 1, wherein a thickness of the IDT electrode included in the first series arm resonator is larger than a thickness of the IDT electrode included in the second series arm resonator.

5. The acoustic wave filter according to claim 1, wherein the first series arm resonator includes a dielectric film on the IDT electrode.

6. The acoustic wave filter according to claim 1, wherein
the first series arm resonator includes a dielectric film on the IDT electrode;
the second series arm resonator includes a dielectric film on the IDT electrode; and
a thickness of the dielectric film on the IDT electrode included in the first series arm resonator is larger than a thickness of the dielectric film on the IDT electrode included in the second series arm resonator.

7. The acoustic wave filter according to claim 1, wherein an electrode line width of the IDT electrode included in the first series arm resonator is wider than an electrode line width of the IDT electrode included in the second series arm resonator.

8. An acoustic wave filter comprising:
an input terminal;
an output terminal;
a series arm circuit which includes a plurality of series arm resonators connected in series between the input terminal and the output terminal; and
a parallel arm circuit which includes at least one parallel arm resonator connected between the series arm circuit and a ground potential; wherein
each of the plurality of series arm resonators is a surface acoustic wave (SAW) resonator including a piezoelectric substrate and an interdigital transducer (IDT) electrode on the piezoelectric substrate, and has a characteristic that a fractional band width increases with a decrease in a thickness of the piezoelectric substrate which is normalized with a wavelength of a signal passing through the series arm resonator; and
a wavelength of a signal passing through one of the plurality of series arm resonators with a lowest anti-resonant frequency is shorter than wavelengths of signals passing through remaining ones of the plurality of series arm resonators.

9. An acoustic wave filter comprising:
an input terminal;
an output terminal;
a series arm circuit which includes a plurality of series arm resonators connected in series between the input terminal and the output terminal; and
a parallel arm circuit which includes at least one parallel arm resonator connected between the series arm circuit and a ground potential; wherein
each of the plurality of series arm resonators is a surface acoustic wave (SAW) resonator including a piezoelectric substrate and an interdigital transducer (IDT) electrode on the piezoelectric substrate;
a thickness of the piezoelectric substrate is less than or equal to about 0.7λ, where λ is a wavelength of a signal passing through the series arm resonator; and
a wavelength of a signal passing through one of the plurality of series arm resonators with a lowest anti-resonant frequency is shorter than wavelengths of signals passing through remaining ones of the plurality of series arm resonators.

10. An acoustic wave filter comprising:
an input terminal;
an output terminal;
a series arm circuit which includes a first series arm resonator and a second series arm resonator connected in series between the input terminal and the output terminal; and
a parallel arm circuit which includes at least one parallel arm resonator connected between the series arm circuit and a ground potential; wherein
each of the first series arm resonator and the second series arm resonator is a surface acoustic wave (SAW) resonator including a piezoelectric substrate and an interdigital transducer (IDT) electrode on the piezoelectric substrate;
a thickness of the piezoelectric substrate is less than or equal to about 0.7λ where λ is a wavelength of a signal passing through the series arm resonator;
an anti-resonant frequency of the first series arm resonator is lower than an anti-resonant frequency of the second series arm resonator; and
a wavelength of a signal passing through the first series arm resonator is shorter than a wavelength of a signal passing through the second series arm resonator.

11. The acoustic wave filter according to claim 8, wherein each of the plurality of series arm resonators includes a reflecting layer on a surface of the piezoelectric substrate opposite to a surface on which the IDT electrode is provided.

12. The acoustic wave filter according to claim 8, wherein an electrode finger pitch of the IDT electrode of the one of the plurality of series arm resonators with the lowest anti-resonant frequency is shorter than wavelengths of the signals passing through remaining ones of the plurality of series arm resonators.

13. The acoustic wave filter according to claim 9, wherein each of the plurality of series arm resonators includes a reflecting layer on a surface of the piezoelectric substrate opposite to a surface on which the IDT electrode is provided.

14. The acoustic wave filter according to claim 9, wherein an electrode finger pitch of the IDT electrode of the one of the plurality of series arm resonators with the lowest anti-resonant frequency is shorter than wavelengths of the signals passing through remaining ones of the plurality of series arm resonators.

15. The acoustic wave filter according to claim 10, wherein each of the first series arm resonator and the second series arm resonator includes a reflecting layer on a surface of the piezoelectric substrate opposite to a surface on which the IDT electrode is provided.

16. The acoustic wave filter according to claim 10, wherein an electrode finger pitch of the IDT electrode of the first series arm resonator is smaller than an electrode finger pitch of the IDT electrode of the second series arm resonator.

17. The acoustic wave filter according to claim 10, wherein a thickness of the IDT electrode included in the first series arm resonator is larger than a thickness of the IDT electrode included in the second series arm resonator.

18. The acoustic wave filter according to claim 10, wherein the first series arm resonator includes a dielectric film on the IDT electrode.

19. The acoustic wave filter according to claim 10, wherein
the first series arm resonator includes a dielectric film on the IDT electrode;
the second series arm resonator includes a dielectric film on the IDT electrode; and
a thickness of the dielectric film on the IDT electrode included in the first series arm resonator is larger than a thickness of the dielectric film on the IDT electrode included in the second series arm resonator.

20. The acoustic wave filter according to claim 10, wherein an electrode line width of the IDT electrode included in the first series arm resonator is wider than an electrode line width of the IDT electrode included in the second series arm resonator.
